(19) United States
(12) Patent Application Publication
(10) Pub. No.: US 2008/0212062 A1
(43) Pub. Date: Sep. 4, 2008

(54) EXPOSURE APPARATUS AND METHOD OF MANUFACTURING DEVICE

(75) Inventor: Tetsuya Taguchi, Utsunomiya-shi (JP)

Correspondence Address: MORGAN & FINNEGAN, L.L.P., 3 WORLD FINANCIAL CENTER, NEW YORK, NY, 10281-2101, US

(73) Assignee: CANON KABUSHIKI KAISHA, Tokyo (JP)

(21) Appl. No.: 12/033,113

(22) Filed: Feb. 19, 2008

(30) Foreign Application Priority Data
Feb. 21, 2007 (JP) 2007-041275

(51) Int. Cl. G03B 27/62; G03F 7/26

(52) U.S. Cl. 355/75; 430/322

(57) ABSTRACT

An exposure apparatus which comprises a reticle stage configured to hold a reticle, and executes multiple exposure of a substrate in a lot to light using a plurality of reticles. The apparatus comprises a calculator configured to calculate a conveyance times taken to convey each of the plurality of reticles to the reticle stage, based on arrangements of the plurality of reticles before start of a process of the lot and a controller configured to determine a sequence in which the plurality of reticles are used, based on the conveyance times of the plurality of reticles calculated by the calculator.

### BACKGROUND OF THE INVENTION

1. Field of the Invention

The present invention relates to an exposure apparatus and a method of manufacturing a device.

2. Description of the Related Art

In recent years, a semiconductor exposure apparatus is required to further improve the throughput.

To improve the throughput when a plurality of reticles are used for one wafer, one prior art optimizes the reticle use sequence for each wafer in a lot for exposing a plurality of wafers. For example, three wafers are exposed using three reticles A, B, and C normally in sequences designated by the user, typically A→B→C, A→B→C, A→B→C, . . . . By optimizing the reticle use sequences for all the wafers in the lot to A→B→C, C→B→A, A→B→C, . . . , the number of times of reticle exchange can be reduced (in this case, it can be reduced by one) as compared with the normal case, thus improving the throughput. However, this prior art optimizes the reticle use sequences for wafers subsequent to the first wafer, on the basis of the reticle use sequence for the first wafer. Therefore, the reticle use sequence for the first wafer is not optimized. This technique uses reticles in a sequence set in the exposure condition of the first wafer without taking account of used reticle information in executing a lot. If the time taken to convey a reticle used first for the first wafer to a reticle stage is shorter than those taken to convey reticles used second and subsequent times for the first wafer to it, the throughput decreases upon inputting a lot.

Japanese Patent Laid-Open No. 2001-267209 discloses another prior technique of changing the lot process sequence in the following way. That is, the times taken to convey reticles to the reticle stage are calculated to specify a reticle conveyed within a shortest time. Then, a lot which uses the specified reticle first is selected and executed. However, this prior art cannot execute lots in the sequence in which the user inputs them, and does not take account of a case in which a plurality of reticles are used.

### SUMMARY OF THE INVENTION

It is an exemplary object of the present invention to improve the throughput of an exposure apparatus which executes multiple exposure of a substrate in a lot to light using a plurality of reticles.

According to the present invention, there is provided an exposure apparatus which comprises a reticle stage configured to hold a reticle, and executes multiple exposure of a substrate in a lot to light using a plurality of reticles, the apparatus comprising a calculator configured to calculate a conveyance times taken to convey each of the plurality of reticles to the reticle stage, based on arrangements of the plurality of reticles before start of a process of the lot, and a controller configured to determine a sequence in which the plurality of reticles are used, based on the conveyance times of the plurality of reticles calculated by the calculator.

According to the present invention, it is possible to improve the throughput of, e.g., an exposure apparatus which executes multiple exposure on a substrate in a lot using a plurality of reticles.

Further features of the present invention will become apparent from the following description of exemplary embodiments with reference to the attached drawings.

### BRIEF DESCRIPTION OF THE DRAWINGS

FIG. 1 is a block diagram showing the system configuration of an exposure apparatus;

FIG. 2 is a data flow diagram of a controller;

FIG. 3 is a flowchart illustrating how to determine the reticle use sequence for the first wafer;

FIG. 4 is a flowchart illustrating how to control a management unit which manages reticle information to calculate the time taken to convey a reticle to an RS;

FIG. 5 is a view showing an example of each of the reticle use sequence and reticle information data at the start of a lot process;

FIG. 6 is a view showing another example of each of the reticle use sequence and the reticle information data at the start of the lot process;

FIG. 7 is a view showing an example of the prediction of reticle information at the end of the lot process;

FIG. 8 is a flowchart illustrating how to return the process when the prediction of the reticle information changes upon stopping a preceding lot process;

FIG. 9 is a flowchart for explaining the manufacture of a device using an exposure apparatus; and

FIG. 10 is a flowchart illustrating details of the wafer process in step S4 of the flowchart illustrated in FIG. 9.

### DESCRIPTION OF THE EMBODIMENTS

Embodiments of the present invention will be described with reference to the accompanying drawings. In the following description, a reticle stage, a wafer stage (substrate stage), and a prealignment unit for aligning a reticle will be referred to as an RS, WS, and PRA, respectively. Also, a pellicle particle inspection unit (checking unit) for inspecting a foreign substance on a pellicle which protects a reticle from dust (foreign substance), and a reticle barcode reader will be referred to as a PPC and PBCR, respectively.

[Embodiment of Exposure Apparatus]

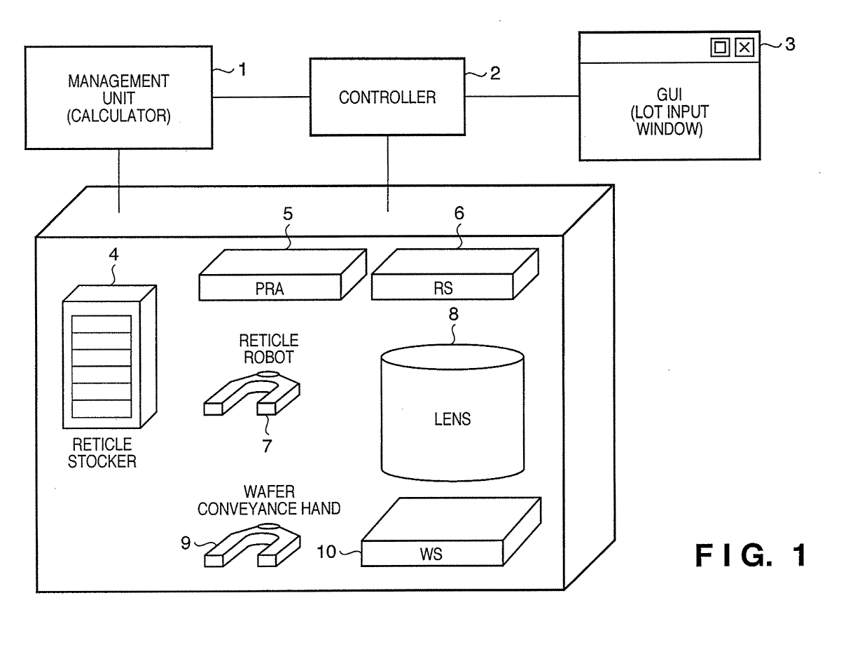

FIG. 1 shows an example of the configuration of an exposure apparatus which has a reticle stage for holding a reticle, and executes multiple exposure on a wafer (substrate) in a lot using a plurality of reticles according to the present invention. The exposure apparatus also has a projection optical system 8 for projecting light from the reticle onto the wafer, a WS 10, an RS 6, a reticle stocker 4, a PRA 5, a reticle robot (a robot configured to convey a reticle) 7, and a wafer conveyance hand 9. The reticle stocker 4 stores reticles, and the PRA 5 aligns them. The reticle robot 7 conveys a reticle from the reticle stocker 4 to the PRA 5. The wafer conveyance hand 9 conveys a wafer to the WS 10.

The exposure apparatus also has a management unit (calculator) 1 for managing reticle information, a graphical user interface (GUI) 3 which includes a display and allows the user to designate a lot to be input, and a controller 2 for controlling the management unit 1 and all the hardware. The management unit 1 manages information (e.g., the number, arrangement position, the necessity of a pellicle check, the necessity of a barcode process, and the time taken to convey a reticle to the RS) about all reticles used in an input lot. As will be described later, the management unit 1 also functions as a calculator which calculates the times taken to respectively convey a plurality of reticles to the RS 6, on the basis of the arrangements of the plurality of reticles before the start of a lot process. Although the reticle stocker 4 is used to store reticles in this embodiment, a reticle pod or the like may be used.

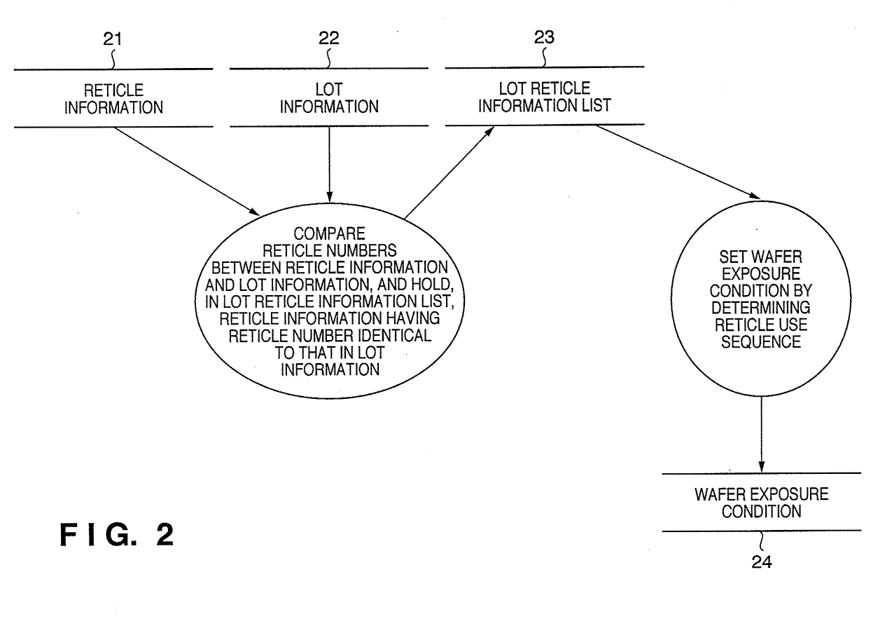

FIG. 2 is a data flow diagram of the above-described controller 2. “Reticle information 21” stores information about all reticles used in an input lot, such as the number, the arrangement position, the necessity of a pellicle check, the necessity of a barcode process, and the time taken to convey a reticle to the RS. “Lot information 22” stores information such as the number of wafers to be exposed, a list of the numbers of reticles to be used, and the exposure condition of each wafer. A “lot reticle information list 23” stores information about reticles used in a lot. “Wafer exposure condition 24” stores information such as the reticle use sequence and exposure dose.

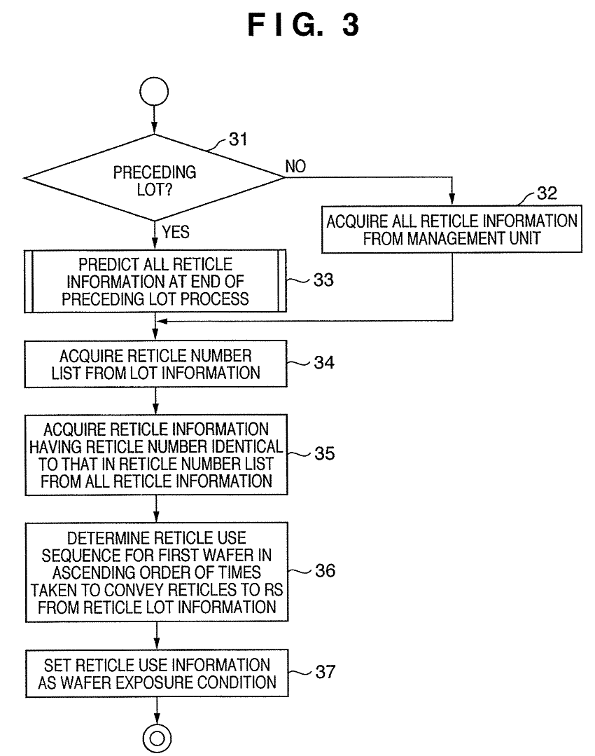

FIG. 3 is a flowchart illustrating details of processes of “Comparing reticle numbers between reticle information and lot information, and holding, in lot reticle information list, reticle information having reticle number identical to that in lot information” and “Setting wafer exposure condition by determining reticle use sequence” indicated in FIG. 2. A procedure for determining the reticle use sequence for the first wafer in a lot for executing multiple exposure on a plurality of wafers using a plurality of reticles will be explained.

In step 31, the controller 2 identifies, from the GUI 3, whether a previously input lot exists when a new lot is input.

A procedure when no previously input lot exists is as follows. In step 32, the controller 2 acquires all reticle information 21 managed by the management unit 1. In step 34, the controller 2 acquires a list of reticle numbers contained in lot information 22 about an input lot. In step 35, the controller 2 holds, in a lot reticle information list 23, reticle information which is acquired in step 32 and has a reticle number identical to that in the reticle number list acquired in step 34. In step 36, the controller 2 determines the ascending order of the times taken to convey the reticles to the RS as the reticle use sequence for the first wafer from the lot reticle information list 23. In step 37, the controller 2 sets the reticle use sequence determined in step 36 as a wafer exposure condition parameter, and displays it on the GUI.

If the controller 2 determines in step 31 that a preceding lot being processed in the exposure apparatus exists, a procedure for controlling the controller 2 to determine the sequence in which a plurality of reticles are used in accordance with the processing history of the preceding lot is as follows. In step 33, the controller 2 predicts, on the basis of lot information about the preceding lot, all reticle information when a process of all wafers belonging to the preceding lot is complete. The controller 2 sets the predicted reticle information as reticle information at the start of a process of a newly input lot. In step 34, the controller 2 acquires, from the management unit 1, a list of reticle numbers contained in lot information 22 about an input lot. In step 35, the controller 2 holds, in a lot reticle information list 23, reticle information which is acquired in step 33 and has a reticle number identical to that in the reticle number list acquired in step 34. A procedure in step 36 and subsequent steps is the same as above. When a plurality of preceding lots exist, the wafer exposure condition of the next preceding lot is determined on the basis of lot information about the first preceding lot. Hence, reticle information at the start of a newly input lot is set only by referring to lot information about the last preceding lot.

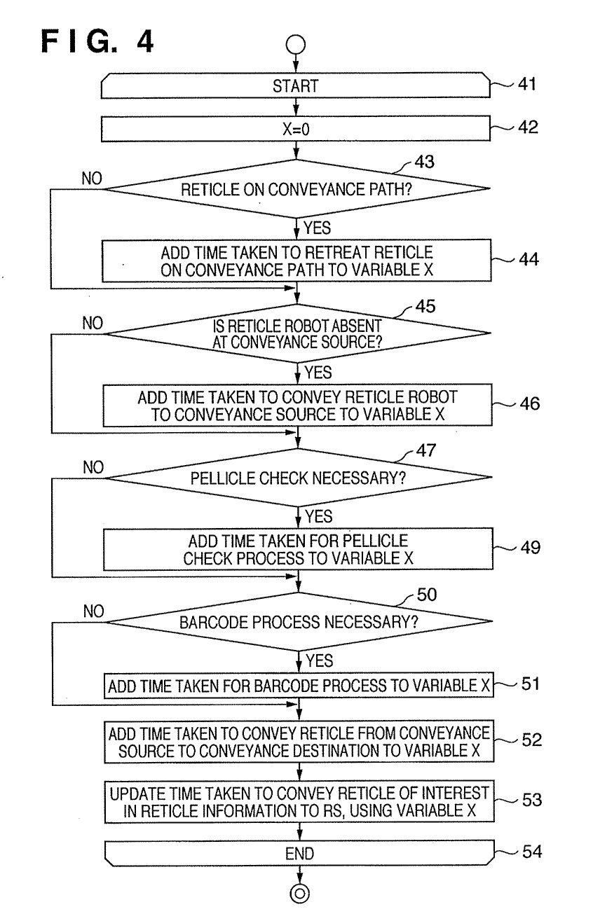

FIG. 4 is a flowchart illustrating an example of a procedure for controlling the management unit 1 to calculate the time taken to convey a reticle to the RS. The management unit functions as a calculator which calculates the times taken to respectively convey a plurality of reticles to the RS 6, on the basis of the arrangements of the plurality of reticles before the start of a lot process. Table 1 shows an example of the times taken to convey reticles from conveyance sources to conveyance destinations. Table 2 shows an example of the times taken for, e.g., a pellicle check and barcode process. The barcode process is executed to read a barcode which stores, e.g., the number of a reticle and is attached to it.

The time taken to convey each of a plurality of reticles to the RS in reticle information is the sum of, e.g., the following times:

(1) the time taken to convey the reticle robot to the arrangement position (conveyance source) of each of the plurality of reticles;

(2) the times taken for, e.g., a pellicle check (foreign substance inspection) and barcode reading process executed for each of the plurality of reticles;

(3) the time taken to convey each of the plurality of reticles from its arrangement position (conveyance source) to the reticle stage (conveyance destination); and

(4) the time taken to retreat a reticle on the conveyance path between the reticle stage and the arrangement position of each of the plurality of reticles.

Upon receiving a reticle conveyance instruction from the controller 2, the reticle robot 7 conveys a designated reticle. As the reticle arrangement and the like change, it is necessary to update not only information about the conveyed reticle but also other reticle information as needed.

A procedure for calculating the times taken to convey all reticles used in an input lot to the RS will be explained below with reference to FIG. 4 and Tables 1 and 2.

In step 41, the management unit 1 starts a procedure for calculating the time taken to convey a reticle to the RS. In step 42, the management unit 1 acquires reticle information of interest, and initializes a variable X for holding the result of the time taken to convey the reticle to the RS. In step 43, the management unit 1 checks whether another reticle is present on the conveyance path of the reticle of interest. If another reticle is present on the conveyance path of the reticle of interest, in step 44 the management unit 1 adds the time taken to convey this reticle to a retreat position to the variable X. In step 45, the management unit 1 checks whether the reticle robot 7 is present at the position of the reticle of interest. If the reticle robot 7 is absent at the position of the reticle of interest, in step 46 the management unit 1 adds the time taken to convey the reticle robot 7 to the position of the reticle of the interest to the variable X. In step 47, the management unit 1 checks whether the reticle of interest requires a pellicle check. If the reticle of interest requires the pellicle check, in step 48 the management unit 1 adds the time taken for the pellicle check to the variable X. In step 50, the management unit 1 checks whether a barcode reading process is necessary by referring to the necessity of the barcode reading process in the reticle information 21. If the barcode reading process is necessary, in step 51 the management unit 1 adds the time taken for the barcode process to the variable X. In step 52, the management unit 1 adds the time taken to convey the reticle of interest from the conveyance source to the conveyance destination. In step 53, the management unit 1 updates the time taken to convey the reticle of interest in the reticle information to the RS, using the variable X. In step 54, the management unit 1 ends the procedure after updating all the reticle information.

TABLE 1

| | | | | | | | Stocker |
|---|---|---|---|---|---|---|---|
| | RS | PRA | PPC | PBCR | Stocker 1 | Stocker 2 | 3 |
| RS | 0 | 3 | 7 | 7 | 6 | 7 | 8 |
| PRA | 3 | 0 | 4 | 4 | 3 | 4 | 5 |
| PPC | 7 | 4 | 0 | 2 | 5 | 5 | 5 |
| PBCR | 7 | 4 | 2 | 0 | 5 | 5 | 5 |
| Stocker 1 | 6 | 3 | 5 | 5 | 0 | 1 | 1 |
| Stocker 2 | 7 | 4 | 5 | 5 | 1 | 0 | 1 |
| Stocker 3 | 8 | 5 | 5 | 5 | 1 | 1 | 0 |

Row: Conveyance destination,
Column: Conveyance source
(unit: sec)

TABLE 2

| PPC | PBCR |
|---|---|
| 10 | 5 |

(unit: sec)

When the management unit 1 manages, e.g., the differences in conveyance times, which depend on the shapes (heights) of the reticle stocker and pod in addition to the above-described information, it can more accurately calculate the time taken to convey the reticle to the RS.

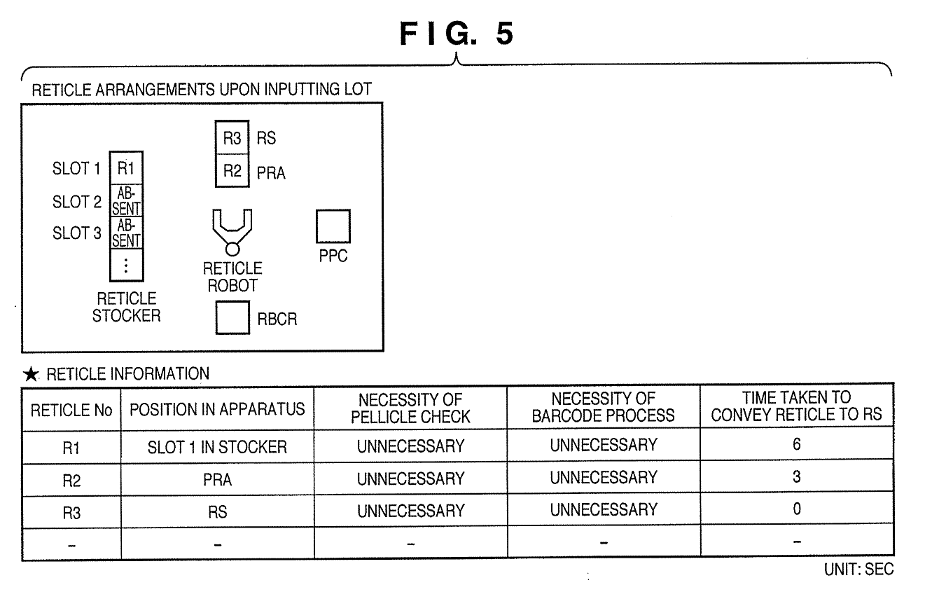

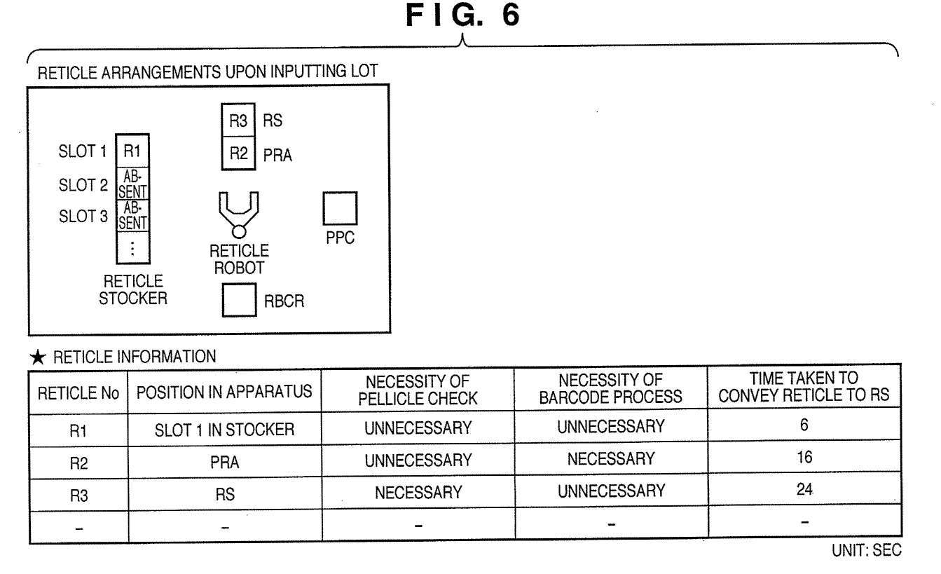

FIGS. 5 and 6 are examples of typical values of each data store shown in FIG. 2. How to practically determine the reticle use sequence on the basis of these data will be explained below.

Reticle information is always updated by calculating the time taken to convey a reticle to the RS. The times taken to convey all reticles used in a lot are acquired in accordance with the flowchart in FIG. 3, and the ascending order of the conveyance times is set as the exposure condition of the first wafer.

Referring to FIG. 5, the times taken to convey reticles to the RS are R3<R2<R1. Hence, the reticle use sequence as the exposure condition of the first wafer is set to R1→R2→R3.

Referring to FIG. 6, the times taken to convey reticles to the RS are R1<R2<R3. Hence, the reticle use sequence as the exposure condition of the first wafer is set to R1→R2→R3.

Each of the PPCs shown in FIGS. 5 and 6 is a position for inspecting a foreign substance on a pellicle which protects a reticle from dust (foreign substance), and each of the RBCRs is a position for reading a barcode which records reticle information such as the reticle number. Although only reticle stockers are shown in FIGS. 5 and 6 as the reticle retreat positions, it is also possible to use reticle processing positions such as the PPCs and RBCRs as the retreat positions.

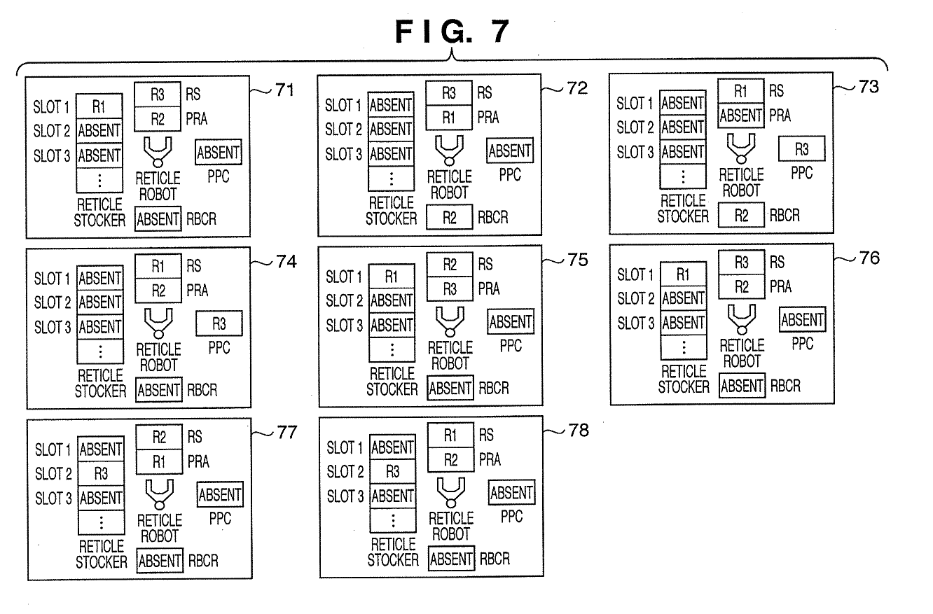

FIG. 7 is a view showing details of the process in step 33 illustrated in FIG. 3.

Assume, for example, that a lot for exposing two wafers W1 and W2 using three reticles R1 to R3 is input to a semiconductor exposure apparatus, and reticle information at the start of a process of the lot is as shown in FIG. 6. How to predict reticle information at the start of a process of a newly input lot in this state will be explained in detail with reference to FIG. 7.

Referring to FIG. 6, the reticle use sequence for the wafer W1 is R1→R2→R3. To increase the throughput, the reticle use sequences for wafers subsequent to the first wafer are determined so as to reduce the number of times of reticle exchange. The reticle use sequence for the wafer W2 is R3→R2→R1.

First, in a current initial state 71, the reticle R2 is retreated to convey the reticle R1 to the RS. At this time, since the reticle R2 requires the barcode process, it is conveyed from the PRA to the PBCR and undergoes the barcode process. The reticle R1 is conveyed to the PRA to set a state 72. The reticle R1 is exchanged with the reticle R3 and the wafer W1 is exposed using the reticle R1. Since the reticle R3 requires the pellicle check, it is conveyed to the PPC during the exposure process of the wafer W1 using the reticle R1 and undergoes the pellicle check (state 73). After completing the barcode process of the reticle R2, the necessity of the barcode process of reticle information about the reticle R2 is set to “unnecessary”, and it is conveyed to the PRA so as to be used in exposing the wafer W1 (state 74). After completing the exposure process of the wafer W1 using the reticle R1, the reticle R1 is exchanged with the reticle R2 and the wafer W1 is exposed using the reticle R2. The reticle R1 is retreated to slot 1 in the reticle stocker during the exposure process using the reticle R2 to convey the reticle R3 used in exposing the wafer W1 next. After completing the pellicle check of the reticle R3, the necessity of the pellicle check in reticle information about the reticle R3 is set to “unnecessary”, and it is conveyed to the PRA (state 75). After completing the exposure process of the wafer W1 using the reticle R2, the reticle R2 is exchanged with the reticle R3 and the wafer W1 is exposed using the reticle R3 (state 76). After completing the exposure process of the wafer W1 using the reticle R3, the wafer W1 is exchanged with the wafer W2 and the wafer 2 is exposed using the reticle R3. After completing the exposure process of the wafer W2 using the reticle R3, the reticle R3 is exchanged with the reticle R2 and the wafer W2 is exposed using the reticle R2. The reticle R3 is retreated to slot 2 in the reticle stocker during the exposure process of the wafer W2 using the reticle R2 to convey the reticle R1 used in exposing the wafer W2 next (state 77). After completing the exposure process of the wafer W2 using the reticle R2, the reticle R2 is exchanged with the reticle R1 and the wafer W2 is exposed using the reticle R1 (state 78). Lastly, the lot process is completed after exposing the wafer W2 using the reticle R1. Hence, reticle information at the start of a process of a newly input lot is as shown in Table 3.

TABLE 3

| | | Necessity | Necessity | Time taken to |
|---|---|---|---|---|
| | Position in | of pellicle | of barcode | convey |
| Reticle No | apparatus | check | process | reticle to RS |
| R1 | RS | unnecessary | unnecessary | 0 |
| R2 | PRA | unnecessary | unnecessary | 3 |
| R3 | slot 2 in | unnecessary | unnecessary | 7 |
| | stocker | | | |
| — | — | — | — | — |

(unit: sec)

As described above, reticle information at the end of a process of the current lot (at the start of a process of the next lot) can be predicted on the basis of, e.g., reticle information at the start of the process of the current lot, and the numbers of reticles used in this lot and the number of wafers to be exposed.

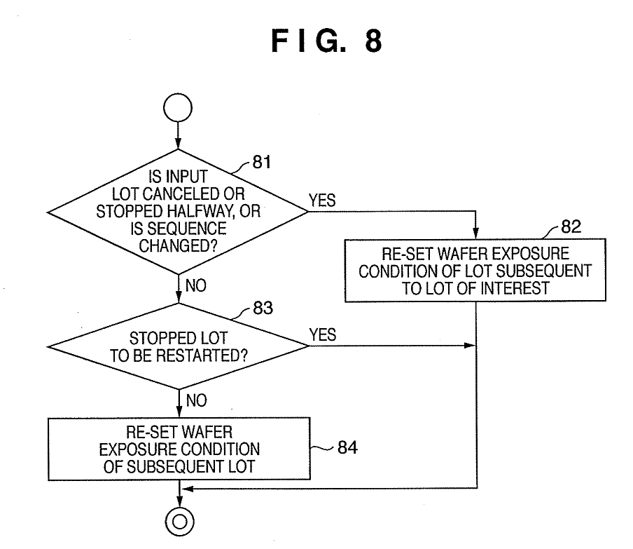

FIG. 8 is a flowchart illustrating a process for re-setting the wafer exposure condition in a subsequent lot when the exposure of a preceding lot is canceled or stopped halfway, or the exposure sequence is changed while a plurality of lots are input.

In this case, reticle information at the start of a process of a subsequent lot to be input later is changed. To prevent a decrease in throughput, it is necessary to re-set the wafer exposure condition.

In step 81, the controller 2 determines whether the exposure of a preceding lot is canceled or stopped halfway, or the exposure sequence is changed. If YES in step 81, in step 82 the controller 2 re-sets the wafer exposure condition of a lot subsequent to a lot of interest in accordance with the flowchart in FIG. 3. When the exposure of the lot is stopped, the necessity of wafer exposure condition re-setting is determined depending on whether to restart the process of the stopped lot (step 83). If the lot process is restarted, it is unnecessary to change the wafer exposure condition of a subsequent lot. However, this does not apply to a case in which another lot is executed during the stopping. If the process of the stopped lot directly ends without being restarted, in step 84 the controller 2 re-sets the wafer exposure condition from a lot subsequent to the stopped lot in accordance with the flowchart in FIG. 3.

The above-described embodiment has exemplified a case in which a plurality of reticles are used for one wafer and a plurality of wafers are exposed. However, the present invention is also applicable to, e.g., a case in which a plurality of exposure conditions are set for one wafer and exposure is executed, and a case in which an exposure process is executed using a multilayer reticle, and a case of a multiple exposure process.

In the above-described manner, a lot for exposing a plurality of wafers using a plurality of reticles for one wafer is processed by determining the reticle use sequence using a wafer exposure condition setting method according to the present invention.

[Embodiment of Manufacture of Device]

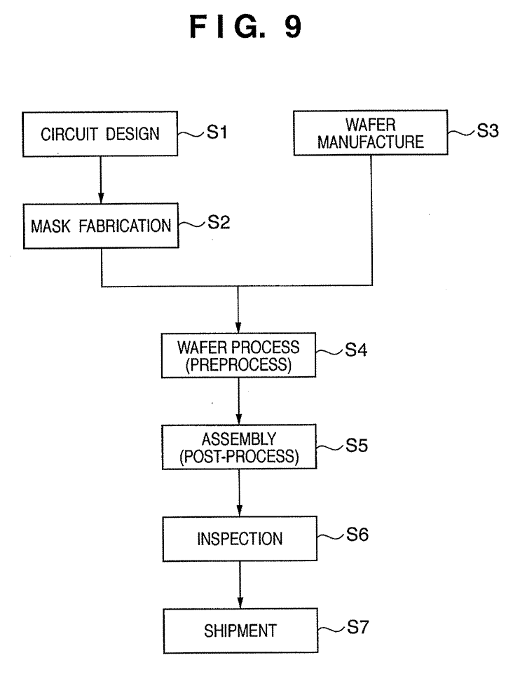

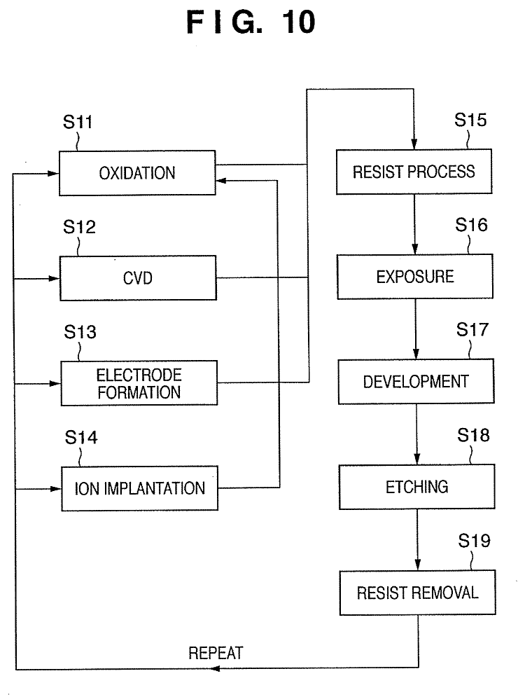

An embodiment of a method of manufacturing a device using the above-described exposure apparatus will be explained with reference to FIGS. 9 and 10.

FIG. 9 is a flowchart for explaining the manufacture of a device (e.g., a semiconductor chip such as an IC or LSI, an LCD, or a CCD). A method of manufacturing a semiconductor chip will be exemplified here.

In step S1 (circuit design), the circuit of a semiconductor device is designed. In step S2 (mask fabrication), a reticle (mask) is fabricated on the basis of the designed circuit pattern. In step S3 (wafer manufacture), a wafer is manufactured using a material such as silicon. In step S4 (wafer process) called a preprocess, the above-described exposure apparatus forms an actual circuit on the wafer by lithography using the reticle and wafer. In step S5 (assembly) called a post-process, a semiconductor chip is formed using the wafer manufactured in step S4. This step includes processes such as assembly (dicing and bonding) and packaging (chip encapsulation). In step S6 (inspection), inspections including operation check test and durability test of the semiconductor device manufactured in step S5 are performed. A semiconductor device is completed with these processes and shipped in step S7.

FIG. 10 is a flowchart illustrating details of the wafer process in step S4. In step S11 (oxidation), the wafer surface is oxidized. In step S12 (CVD), an insulating film is formed on the wafer surface. In step S13 (electrode formation), an electrode is formed on the wafer by vapor deposition. In step S14 (ion implantation), ions are implanted into the wafer. In step S15 (resist process), a photosensitive agent is applied on the wafer. In step S16 (exposure), the exposure apparatus transfers the circuit pattern of the mask onto the wafer by exposure. In step S17 (development), the exposed wafer is developed. In step S18 (etching), portions other than the developed resist image are etched. In step S19 (resist removal), any unnecessary resist remaining after etching is removed. By repeating these steps, a multilayered structure of circuit patterns is formed on the wafer.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-041275, filed Feb. 21, 2007, which is hereby incorporated by reference herein in its entirety.

What is claimed is:

1. An exposure apparatus which comprises a reticle stage configured to hold a reticle, and executes multiple exposure of a substrate in a lot to light using a plurality of reticles, the apparatus comprising:
a calculator configured to calculate a conveyance time taken to convey each of the plurality of reticles to the reticle stage, based on arrangement of the plurality of reticles before start of a process of the lot; and
a controller configured to determine a sequence in which the plurality of reticles are used, based on the conveyance times of the plurality of reticles calculated by the calculator.

2. An apparatus according to claim 1, further comprising:
a robot configured to convey a reticle; and
a preprocessing unit configured to execute a preprocess for a reticle,
wherein the controller is configured to calculate the conveyance time of each of the plurality of reticles based on at least one of a time taken to move the robot to a position of each of the plurality of reticles, a time taken to execute the preprocess for each of the plurality of reticles, a time taken to convey each of the plurality of reticles from a position thereof to the reticle stage, and a time taken to retreat a reticle on a conveyance path between a position of each of the plurality of reticles and the reticle stage.

3. An apparatus according to claim 2, wherein the preprocessing unit is configured to execute at least one of inspection of the reticle for a foreign substance and reading of a barcode of the reticle.

4. An apparatus according to claim 1, wherein the controller is configured to determine the sequence, in which the plurality of reticles are used, with respect to a first substrate in the lot.

5. The apparatus according to claim 4, wherein the controller is configured to determine, based on the sequence in which the plurality of reticles are used with respect to the first substrate, the sequence in which the plurality of reticles are used with respect to each of substrates subsequent to the first substrate in the lot, so as to reduce number of times of reticle exchange.

6. An apparatus according to claim 1, wherein
the controller is configured to predict, if a preceding lot being processed exists, arrangement of each of the plurality of reticles at a time when exposure of all substrates in the preceding lot is completed, and the calculator is configured to calculate the conveyance time of each of the plurality of reticles based on the arrangement of each of the plurality of reticles predicted by the controller.

7. An apparatus according to claim 6, wherein the controller is configured to determine the sequence in which the plurality of reticles are used, again in accordance with a processing history of the preceding lot.

8. An apparatus according to claim 1, further comprising a display,
wherein the controller is configured to cause the display to display the determined sequence in which the plurality of reticles are used.

9. A method of manufacturing a device, the method comprising:
exposing a substrate to light using an exposure apparatus defined in claim 1;
developing the exposed substrate; and
processing the developed substrate to manufacture the device.
